(19) United States
(12) Patent Application Publication
(10) Pub. No.: US 2025/0098131 A1
(43) Pub. Date: Mar. 20, 2025

(54) FEEDER, COMPONENT MOUNTING APPARATUS, AND COMPONENT MOUNTING METHOD

(71) Applicant: FUJI CORPORATION, Chiryu (JP)

(72) Inventor: Hiroki MURASE, Nagoya-shi (JP)

(73) Assignee: FUJI CORPORATION, Chiryu (JP)

(21) Appl. No.: 18/725,987

(22) PCT Filed: Jan. 31, 2022
(86) PCT No.: PCT/JP2022/003564

§ 371 Date: Jul. 1, 2024

(51) Int. Cl. H05K 13/02

(52) U.S. Cl. CPC H05K 13/02

(57) ABSTRACT

A feeder for feeding a tape that accommodates a component and supplying the component includes a feeder main body provided with a holding section that holds a disk-shaped reel around which the tape is wound to be rotatable about a central axis, and a plate-shaped cover configured to open and close the holding section. The cover includes an opening at a location corresponding to a region of a board surface of the reel to which an identification code of the reel is able to be given.

### TECHNICAL FIELD

The present description discloses a feeder, a component mounting apparatus, and a component mounting method.

### BACKGROUND ART

Conventionally, a feeder is known to which a disk-shaped reel around which a tape accommodating components is wound is detachably attached and which feeds the tape and supplies the components by rotating the reel. For example, Patent Literature 1 discloses a device in which a reel attached to a feeder is covered with a transparent cover such as an acrylic plate, and an identification code such as a bar code attached to the reel can be read through the transparent cover.

### PATENT LITERATURE

### Patent Literature 1: JP-A-2019-176188

### SUMMARY OF THE INVENTION

### Technical Problem

However, when the above-described feeder is attached to and detached from a component mounting apparatus, a transparent cover can rub against the adjacent feeder. When attachment and detachment accompanied by such rubbing are repeated to cause a flaw in the transparent cover, transparency of the transparent cover is decreased due to aging, and it is difficult to read an identification code.

A main object of the present disclosure is to enable an identification code of a reel to be easily read without being affected by aging.

### Solution to Problem

The present disclosure employs following technology to achieve the main object described above.

A feeder of the present disclosure is a feeder for feeding a tape that accommodates a component and supplying the component, and includes
a feeder main body provided with a holding section that holds a disk-shaped reel around which the tape is wound to be rotatable about a central axis, and
a plate-shaped cover configured to open and close the holding section, in which
the cover includes an opening at a location corresponding to a region of a board surface of the reel to which an identification code of the reel is able to be given.

Since an opening is formed in a cover of a reel in a feeder of the present disclosure, an identification code of the reel can be easily read without being affected by aging.

### BRIEF DESCRIPTION OF DRAWINGS

FIG. 1 is a configuration view schematically illustrating a configuration of component mounting apparatus 10.

FIG. 2 is a configuration view schematically illustrating a configuration of tape feeder 20.

FIG. 3 is a view of reel 40S having a smallest diameter.

FIG. 4 is a view of reel 40L having a largest diameter.

FIG. 5 is a view of tape feeder 20 in which reel 40S is set.

FIG. 6 is a view of tape feeder 20 in which reel 40L is set.

FIG. 7 is a view illustrating an example of an opening region of opening 31.

FIG. 8 is a view of tape feeder 120 of a comparative example in which reel 40S is set.

FIG. 9 is a view of tape feeder 120 of a comparative example in which reel 40L is set.

### DESCRIPTION OF EMBODIMENTS

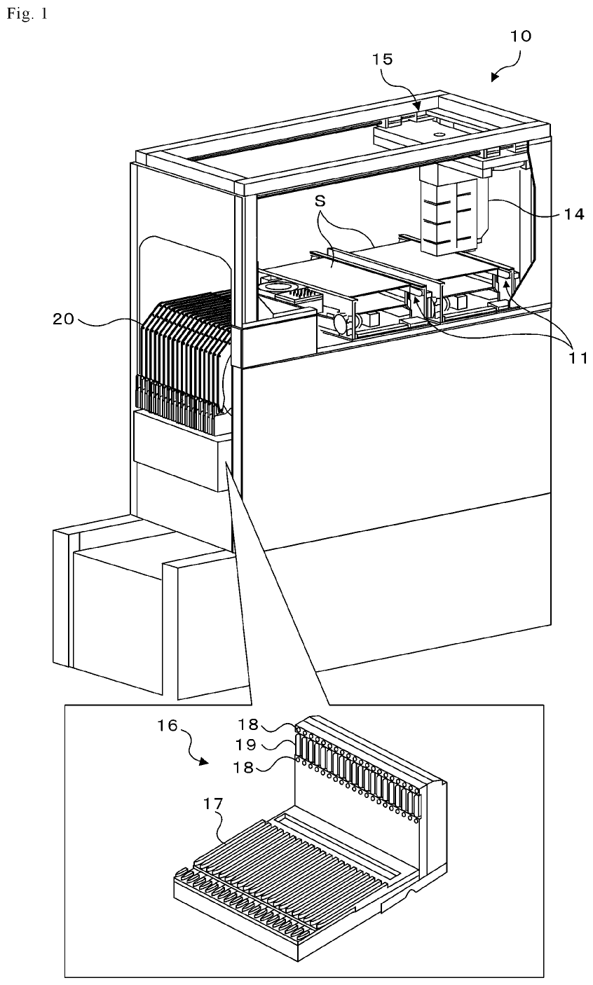

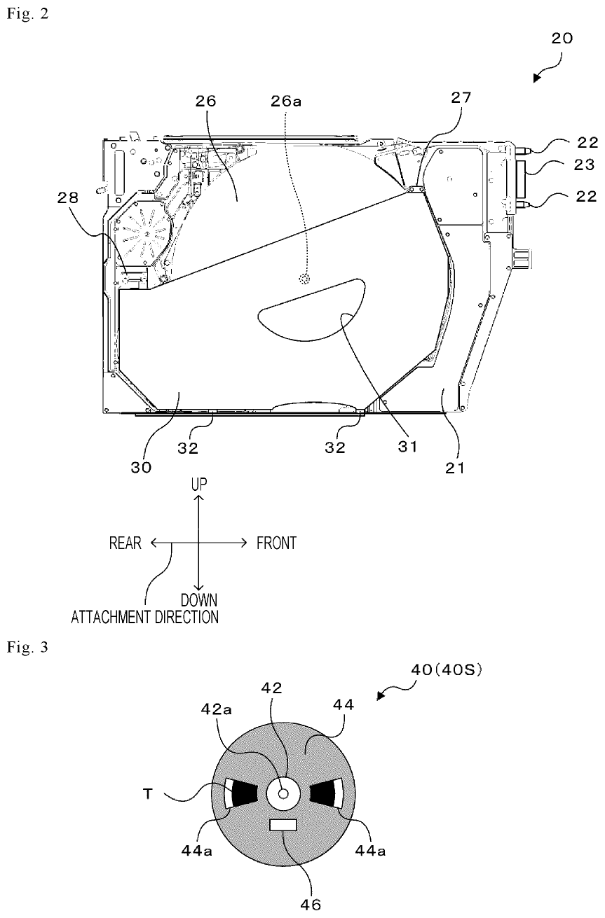

Next, embodiments of the present disclosure will be described with reference to the drawings. FIG. 1 is a configuration view schematically illustrating a configuration of component mounting apparatus 10. FIG. 2 is a configuration view schematically illustrating a configuration of tape feeder 20. As illustrated in FIG. 1, component mounting apparatus 10 includes board conveyance device 11 that conveys board S, tape feeder 20 that supplies a component, head 14 in which a nozzle that picks up the component is disposed to be able to be lifted and lowered, and movement device 15 that moves head 14 in XY directions. Board conveyance device 11 has two pairs of conveyor belts and conveys board S by each conveyor belt.

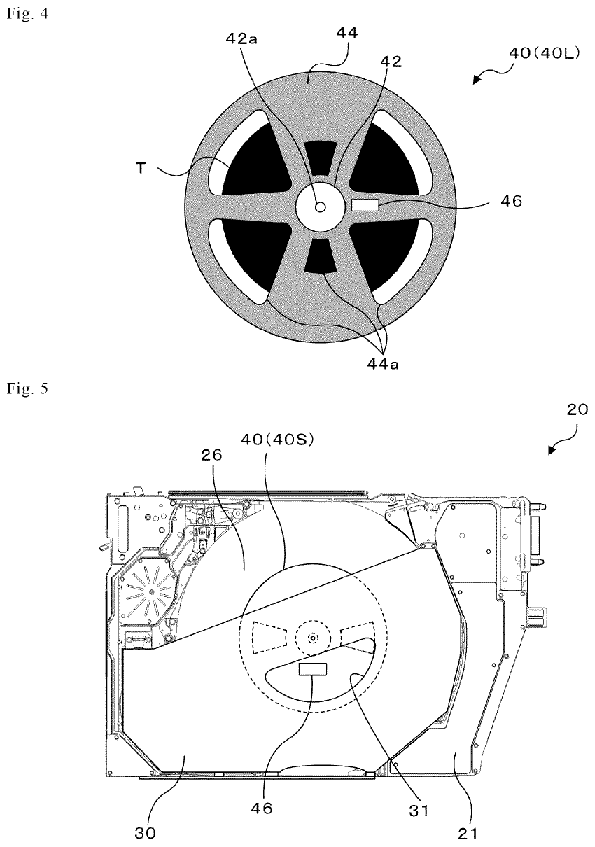

Tape feeder 20 supplies components by feeding, for example, a tape that accommodates components at a predetermined pitch, to a supply position where a nozzle of head 14 can collect the components. Although not illustrated, the tape is configured with a bottom tape in which cavities (recessed section) for accommodating components are formed at predetermined intervals, and a film-like cover tape that covers the bottom tape. In tape feeder 20, reel 40 (see FIGS. 3 and 4) around which a tape is wound is set, the tape is pulled out from reel 40 and fed out to the supply position, and the cover tape is peeled off from the bottom tape before the supply position, and thereby, the components are in a state of being able to be picked up. FIG. 2 illustrates tape feeder 20 in which reel 40 is not set.

Further, multiple tape feeders 20 are aligned in and attached to feeder stand 16 provided in component mounting apparatus 10. Feeder stand 16 is an L-shaped stand in a side view and includes multiple slots 17, two positioning holes 18 corresponding to each slot 17, and connector 19 corresponding to each slot 17. Attachment of tape feeder 20 to feeder stand 16 is made by inserting tape feeder 20 into slot 17 and sliding tape feeder 20. In component mounting apparatus 10, multiple types of components are supplied from multiple tape feeders 20 attached to feeder stand 16, and each of the supplied components can be collected by a nozzle of head 14 and mounted on board S.

As illustrated in FIG. 2, tape feeder 20 includes feeder main body 21 provided with reel holder 26 that holds reel 40, and plate-shaped reel cover 30 that opens and closes reel holder 26. In feeder main body 21, two positioning pins 22 and connector 23 are provided on an end portion on a front side in an attachment direction (see FIG. 2) of tape feeder 20 to feeder stand 16 to protrude on a front side in the attachment direction. Two positioning pins 22 are respectively inserted into two positioning holes 18 of feeder stand 16. Connector 23 is provided between two positioning pins 22 and is connected to connector 19 of feeder stand 16.

Reel holder 26 is configured to hold multiple types of reels 40 having different sizes to be rotatable about a central axis, and holding shaft 26a for holding reel 40 is provided in a central portion thereof.

Here, among multiple types of reels 40 having different sizes, reel 40S having the smallest diameter is illustrated in FIG. 3, and reel 40L having the largest diameter is illustrated in FIG. 4. Reels 40S and 40L have similar configurations, and each include winding core section 42 around which tape T is wound to form a central axis, and a pair of disk sections 44 attached to winding core section 42 to grip tape T from both sides. Center hole 42a into which holding shaft 26a of reel holder 26 is inserted is formed in winding core section 42. Multiple cutout windows 44a are formed in disk section 44. An operator can visually recognize tape T (black regions in FIGS. 3 and 4) from cutout windows 44a. Further, identification code 46, such as a bar code or a two-dimensional code for reading identification information, such as the type of components accommodated in reel 40 (tape T), is given to disk section 44. Identification code 46 can be given to a region (a gray region in FIGS. 3 and 4) of disk section 44, which is a region deviated from winding core section 42 and in which cutout windows 44a are not formed. Although the present embodiment illustrates an example in which identification code 46 for reading the identification information is given, a label or the like indicating the identification information may be given such that an operator can check the identification information.

Reel cover 30 is a plate-shaped member that opens and closes reel holder 26 by rotating through support shaft 32 provided at a lower portion, and enables reel 40 to be attached to and detached from reel holder 26 in an open state. Reel cover 30 is formed of a single metal plate and is formed in a size that covers from a lower end of reel holder 26 to above holding shaft 26a in a closed state and exposes an upper portion of reel holder 26. That is, reel cover 30 is formed in a size that covers at least half of a board surface region of reel 40 held by reel holder 26. Further, opening 31 is formed in reel cover 30. Details of opening 31 will be described below.

Tape feeder 20 includes, a lock mechanism that locks reel cover 30, lock mechanism 27 on a front side and lock mechanism 28 on a rear side in an attachment direction of tape feeder 20. Although details of lock mechanisms 27 and 28 are omitted, reel cover 30 is configured to be locked as an operator pushes edge portions on a front upper side and rear upper side of reel cover 30 respectively toward lock mechanisms 27 and 28 and to be unlocked as the operator pushes a release lever upward.

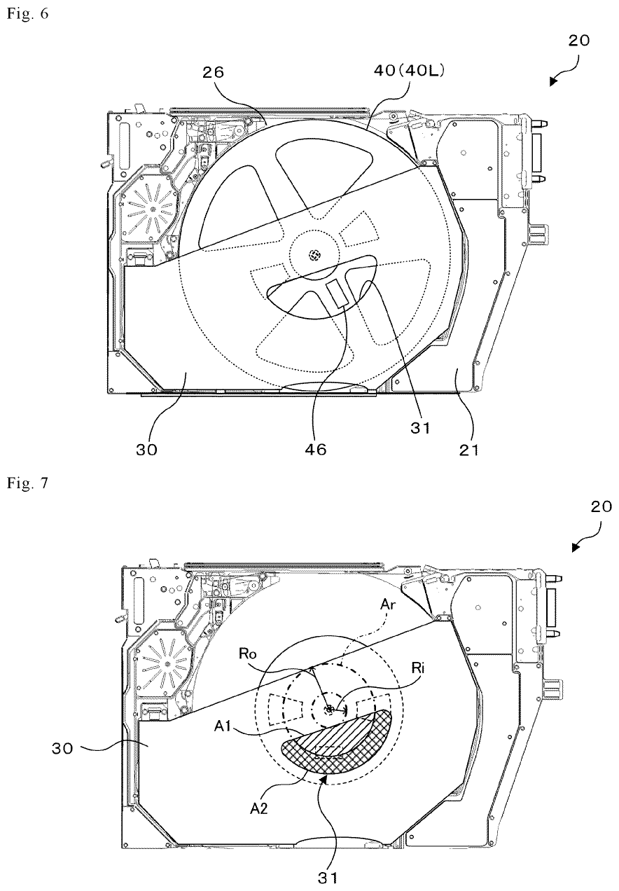

A state in which reels 40 (reels 40S and 40L) are set in tape feeder 20 configured in this way is described. FIG. 5 is a view of tape feeder 20 in which reel 40S is set. FIG. 6 is a view of tape feeder 20 in which reel 40L is set. Tape T is not illustrated in reel 40 in FIG. 5 and thereafter. As described above, opening 31 is provided in reel cover 30 of the present embodiment. Accordingly, as illustrated in FIG. 5 and FIG. 6, identification code 46 of reels 40S and 40L can be exposed through opening 31. Accordingly, an operator can check identification code 46 (identification information) or read identification code 46 by a code reader or the like.

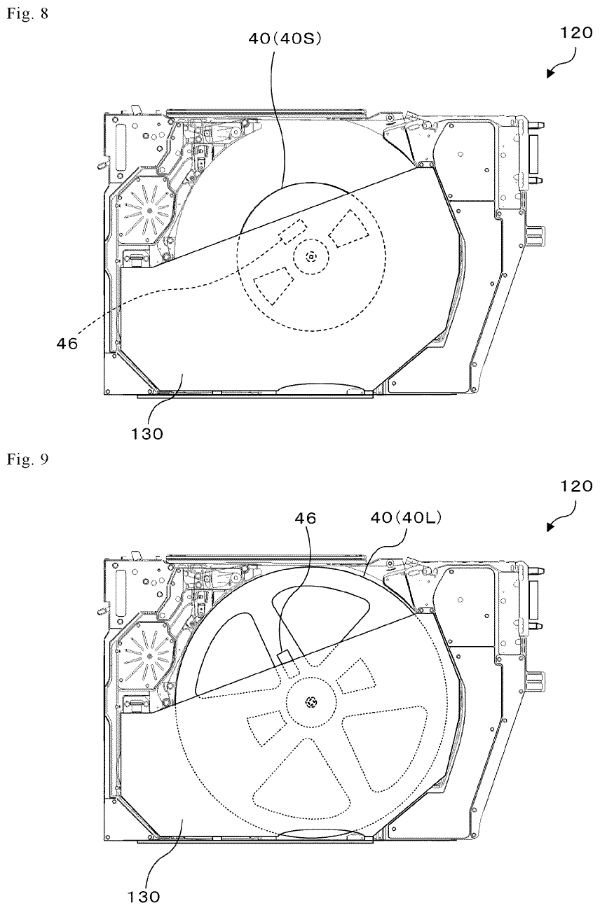

Here, FIG. 7 is a view illustrating an example of an opening region of opening 31. FIG. 8 is a view of tape feeder 120 of a comparative example in which reel 40S is set. FIG. 9 is a view of tape feeder 120 of a comparative example in which reel 40L is set. Tape feeder 120 of the comparative example is different from tape feeder 20 of the present embodiment in that reel cover 130 in which opening 31 is not provided is provided.

As illustrated in FIG. 7, opening 31 has first region A1 and second region A2 as opening regions. In FIG. 7, annular region Ar is indicated by an alternate long and short dash line, in which inner diameter Ri is from the center of reel 40 (40S) to an edge of winding core section 42 and outer diameter Ro is from the center of reel 40 (40S) to an upper edge of reel cover 30. First region A1 is a partial region on a lower side of annular region Ar. Second region A2 has a shape obtained by expanding entire first region A1 radially outward and is a region continuously connected to first region A1. In a case where identification code 46 is given to reel 40 to be located in annular region Ar, even when reel 40 is rotated, identification code 46 is not exposed from an upper edge of reel cover 30 (see FIG. 8), or only a part of identification code 46 is exposed (see FIG. 9). Accordingly, in tape feeder 120 of the comparative example in which opening 31 is not provided, an operator needs to open reel cover 130 to check or read identification code 46.

In contrast to this, in the present embodiment, opening 31 is formed in reel cover 30, and opening 31 has first region A1. Accordingly, even when identification code 46 is given in annular region Ar, an operator can check or read identification code 46 without opening reel cover 30 by locating identification code 46 within opening 31 by performing rotation or the like of reel 40 (see FIGS. 5 and 6). Further, since opening 31 further has second region A2, even when only a part of identification code 46 is exposed from an upper edge of reel cover 30, an operator can check or read identification code 46 without opening reel cover 30 (see FIG. 6).

Further, opening 31 is formed to be a region inside an outer edge of reel 40S having the smallest diameter (see FIG. 5). Accordingly, since the outer edge of reel 40 is not located inside opening 31, the outer edge of reel 40 can be prevented from protruding out of opening 31. Therefore, even when opening 31 is provided in reel cover 30, it is possible to prevent trouble, such as collision of the outer edge of reel 40 protruding from opening 31 with adjacent tape feeder 20 when reel 40 is attached or detached.

Here, a correspondence relationship between elements of the present embodiment and elements of the present disclosure is clarified. Tape feeder 20 of the present embodiment corresponds to a feeder, reel holder 26 corresponds to a holding section, reel cover 30 corresponds to a cover, and opening 31 corresponds to an opening. Head 14 corresponds to a mounting head, and component mounting apparatus 10 corresponds to a component mounting apparatus. In the present embodiment, an example of a component mounting method of the present disclosure is also clarified.

In tape feeder 20 of the present embodiment described above, reel cover 30 is able to easily read identification code 46 (identification information) because opening 31 is formed at a location corresponding to a region of reel 40 where identification code 46 can be given. Further, when reel cover 30 is formed of a resin material with transparency, transparency is reduced due to aging, causing identification code to be difficult to be read, but in the present embodiment, there is no influence of such aging. Further, since reel cover 30 is configured with a single metal plate in which opening 31 is formed, identification code 46 can be easily read while a simple configuration having a small number of components is provided, compared to a configuration in which reel cover 30 is divided into multiple metal plates.

Further, reel cover 30 exposes a part of a board surface (a surface of disk section 44) of reel 40 above an upper edge in a closed state. Opening 31 is formed to include a part of first region A1 of annular region Ar. Accordingly, although identification code 46 is given in a region that is not exposed from reel cover 30 even when reel 40 is rotated, identification code 46 can be easily read through opening 31.

Further, since opening 31 is formed to include second region A2 obtained by expanding first region A1 radially outward, identification code 46 can be more easily read.

Further, since opening 31 is formed to be a region inside an outer edge of reel 40S having a smallest diameter, it is possible to prevent the outer edge of reel 40 from protruding from opening 31 to collide with adjacent tape feeder 20 or the like.

The present disclosure is not limited to the above-described embodiments and can be implemented in various aspects as long as the aspects fall within the technical scope of the present disclosure.

For example, in the embodiments described above, opening 31 is formed in a region inside an outer edge of reel 40S having the smallest diameter, however the configuration is not limited to this, and opening 31 may be formed to include a region outside the outer edge of reel 40S having the smallest diameter.

In the above-described embodiment, opening 31 is formed to include second region A2 obtained by expanding first region A1 radially outward, however the configuration is not limited to this, and opening 31 may be formed to include at least first region A1. Alternatively, opening 31 is not limited to including first region A1 which is a part of annular region Ar and may be formed at a location corresponding to a region where identification code 46 can be given to reel 40.

### INDUSTRIAL APPLICABILITY

The present disclosure can be used in a component mounting field and the like.

### REFERENCE SIGNS LIST

10 component mounting apparatus, 11 board conveyance device, 14 head, 15 movement device, 16 feeder stand, 17 slot, 18 positioning hole, 19 connector, 20, 120 tape feeders, 21 feeder main body, 22 positioning pin, 23 connector, 26 reel holder, 26a holding shaft, 27, 28 lock mechanisms, 30, 130 reel covers, 31 opening, 32 support shaft, 40, 40L, 40S reels, 42 winding core section, 42a center hole, 44 disk section, 44a cutout window, 46 identification code, A1 first region, A2 second region, Ar annular region, Ri inner diameter, Ro outer diameter, S board, T tape

1. A feeder for feeding a tape that accommodates a component and supplying the component, the feeder comprising:
a feeder main body provided with a holding section that holds a disk-shaped reel around which the tape is wound to be rotatable about a central axis; and
a plate-shaped cover configured to open and close the holding section,
wherein the cover includes an opening at a location corresponding to a region of a board surface of the reel to which an identification code of the reel is able to be given.

2. The feeder according to claim 1, wherein
the cover exposes a part of the board surface of the reel above an upper edge in a closed state, and
the opening is formed to include a partial region of an annular region whose inner diameter is an edge of a constituent member of the central axis of the reel and whose outer diameter is from the central axis to the upper edge of the cover.

3. The feeder according to claim 2, wherein
the opening is formed to include the partial region and a region obtained by expanding the partial region radially outward.

4. The feeder according to claim 1, wherein
the opening is formed in a region inside an outer edge of a reel having a smallest diameter among the reels that are held by the holding section.

5. A component mounting apparatus comprising:
the feeder according to claim 1; and
a mounting head configured to collect a component supplied from the feeder and mount the component on a target object.

6. A component mounting method comprising:
(a) a step of supplying a component from the feeder according to claim 1; and
(b) a step of collecting the component supplied in the step (a) and mounting the component on a target object.
